(19) United States
(12) Patent Application Publication
(10) Pub. No.: US 2016/0025788 A1
(43) Pub. Date: Jan. 28, 2016

(54) MODULE SOCKET, DEVICE FOR TESTING WIRELESS MODULE, AND METHOD FOR TESTING WIRELESS MODULE

(71) Applicant: Panasonic Intellectual Property Managment Co., Ltd., Osaka-shi, Osaka (JP)

(72) Inventors: Suguru Fujita, Tokyo (JP); Kohei Sugimoto, Osaka (JP); Kentaro Watanabe, Hyogo (JP)

(21) Appl. No.: 14/772,742

(22) PCT Filed: Nov. 20, 2013
(86) PCT No.: PCT/JP2013/006821

§ 371 Date: Sep. 3, 2015

(30) Foreign Application Priority Data
Mar. 5, 2013 (JP) 2013-043494

(51) Int. Cl. G01R 29/10

(52) U.S. Cl. CPC G01R 29/105

(57) ABSTRACT

An object is to provide a module socket capable of increase the reliability of module characteristics obtained by testing a wireless module. A module socket is equipped with a seat member having a placement surface to come into contact with a mounting surface, mounted with an antenna, of a wireless module having the antenna and a gap formed within a prescribed distance of the antenna in a radio wave radiation direction in a state that the wireless module is set on the placement surface.

### TECHNICAL FIELD

The present disclosure relates to a module socket, a device for testing a wireless module, and a method for testing a wireless module.

### BACKGROUND ART

Conventionally, module performance is tested, for example, before shipment of a product. In testing module performance, a test subject module is placed on a module testing placement stage which is part of a testing instrument. Various characteristics (e.g., circuit characteristics) of the module are tested using the testing instrument.

Incidentally, instruments are known which are used for testing performance of an electronic device by housing an antenna of the electronic device and an antenna for measurement in a test box having a radio wave absorbing body and receiving radio waves emitted from the antenna of the electronic device by the antenna for measurement (refer to Patent document 1, for example).

### PRIOR ART DOCUMENTS

### Patent Documents

Patent document 1: JP-A-2007-225567

### SUMMARY OF THE INVENTION

### Problems to be Solved by the Invention

In the conventional testing instruments, the reliability of module characteristics obtained by testing a wireless module having an antenna is insufficient.

The present disclosure has been made in view of the above circumstances, and provides a module socket, a device for testing a wireless module, and a method for testing a wireless module that can increase the reliability of module characteristics obtained by testing a wireless module.

### Means for Solving the Problems

A module socket according to the disclosure includes a seat member including a placement surface configured to contact with a mounting surface, mounted with an antenna, of a wireless module having the antenna; and a gap formed within a prescribed distance from the antenna in a radio wave radiation direction in a state that the wireless module is set on the placement surface.

### Advantages of the Invention

The disclosure makes it possible to increase the reliability of module characteristics obtained by testing a wireless module.

### BRIEF DESCRIPTION OF THE DRAWINGS

FIG. 1 is a sectional view showing an example overall configuration of a testing device according to a first embodiment.

FIG. 2 is a partial, enlarged sectional view showing a placement stage according to the first embodiment and its neighborhood.

FIGS. 3(A)-3(D) are schematic plan views and schematic sectional views showing example shapes of placement stages according to the first embodiment on which a wireless module or modules are set.

FIG. 4 is a sectional view showing an example shape of a placement stage according to the first embodiment on which the wireless module is set.

FIG. 5 is a sectional view showing a first modification, relating shape, of the placement stage according to the first embodiment on which the wireless module is set.

FIG. 6(A) is a sectional view showing a second modification, relating shape, of the placement stage according to the first embodiment on which the wireless module is set, and FIG. 6(B) is a sectional view showing a third modification, relating shape, of the placement stage according to the first embodiment on which the wireless module is set.

FIGS. 7(A)-7(D) are schematic plan views and schematic sectional views showing example shapes of placement stages according to a second embodiment on which a wireless module or modules are set.

FIG. 8 is a sectional view showing an example shape of a placement stage according to the second embodiment on which the wireless module is set.

FIG. 9(A) is a schematic graph showing an example radiation pattern p of a signal emitted from the antenna of the radiation module in the second embodiment, and FIG. 9(B) is a schematic graph showing an example radiation pattern p of a signal emitted from the antenna of a conventional wireless module.

FIG. 10 is a sectional view showing a first modification, relating shape, of the placement stage according to the second embodiment on which the wireless module is set.

FIG. 11 is a sectional view showing a second modification, relating shape, of the placement stage according to the second embodiment on which the wireless module is set.

FIG. 12(A) is a schematic perspective view, as view from above, of a placement stage auxiliary member that is set in a anechoic box employed in the first embodiment, and FIG. 12(B) is a schematic perspective view as viewed from below from inside the anechoic box employed in the first embodiment.

FIG. 13 is a partial, enlarged sectional view showing an example of a placement stage according to the third embodiment and its neighborhood.

FIG. 14 is a plan view showing an example structure around an opening of the placement stage according to the third embodiment.

FIGS. 15(A)-15(C) are plan views showing modifications of the structure around the opening of the placement stage according to the third embodiment.

FIG. 16 is a sectional view showing an example configuration of part of a testing device including a placement stage according to a fourth embodiment.

FIG. 17(A) is a sectional view showing examples of a module socket according to a fifth embodiment and its neighborhood, and FIG. 17(B) is a plan view showing an example structure around an opening of the module socket according to the fifth embodiment.

### MODES FOR CARRYING OUT THE INVENTION

Embodiments of the present disclosure will be described with reference to the drawings.

### (Background of One Mode of Disclosure)

In conventional module testing instruments, when a wireless module having an antenna are tested for its module characteristics, an antenna for receiving radio waves emitted from a test subject wireless module is attached to the testing instrument. When radio waves are emitted from the wireless module in a state that the wireless module is set on a placement stage, the placement stage which is made of a resin, for example, exists between the antenna of the wireless module and that of the testing instrument. In this case, the placement stage interferes with radio waves emitted from the wireless module to change the radio wave radiation pattern. This lowers the reliability of module characteristics (i.e., a test result) of the wireless module.

A description will be made below of placement stages, wireless module testing devices, and wireless module testing methods that can increase the reliability of module characteristics obtained by testing a wireless module.

The placement stages according to the following embodiments are ones that are provided in a wireless module testing device and on which a wireless module for transmitting and receiving radio waves in a high frequency band including a millimeter wave band, for example, is to be set.

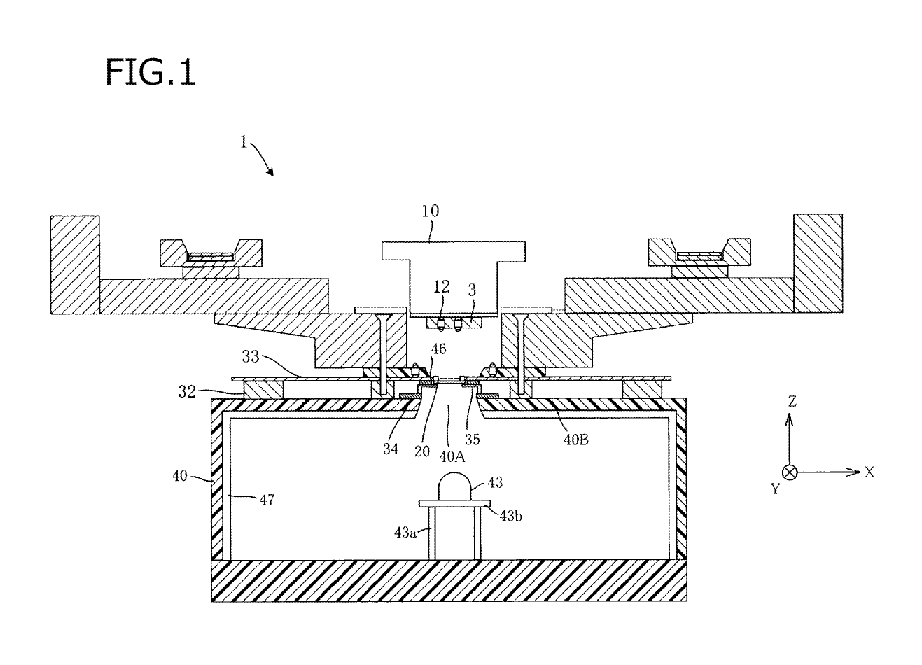

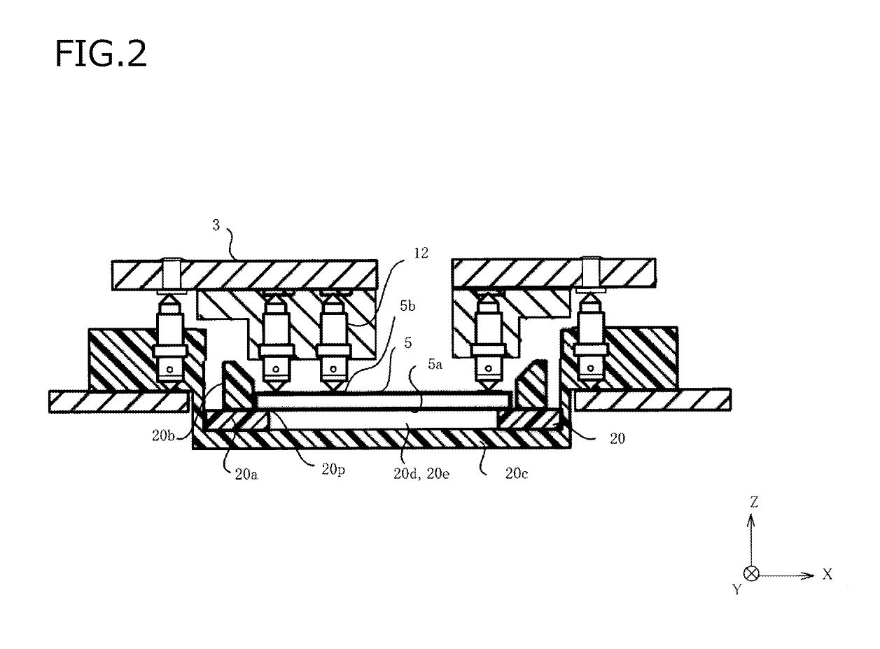

FIG. 1 is a sectional view showing an example overall configuration of a testing device 1 according to the embodiment. FIG. 2 is an enlarged sectional view of part of FIG. 1, that is, a placement stage 20 and its neighborhood. The testing device 1 measures a radiation pattern of radio waves emitted from a wireless module 5 as a test subject (DUT: device under test). The testing device 1 is equipped with an IC handler 3, a pusher 10, the placement stage 20, and an anechoic box 40. The placement stage 20 is an example of a module socket on which the wireless module 5 is to be set.

The IC handler 3 has a suction pad (not shown) for picking up the wireless module 5 and contact pins 12 to be brought into contact with the wireless module 5 when pushed by the pusher 10. The contact pins 12 are an example of contactors.

To set the wireless module 5 on the placement stage 20, the IC handler 3 picks up the wireless module 5 by sucking its surface by means of the suction pad, moves to over the placement stage 20, and places the wireless module 5 on the placement stage 20.

Capable of moving in the vertical direction (Z direction), the pusher 10 lowers to push the contact pins 12 of the IC handler 3. When a prescribed load is imposed on the IC handler 3, the contact pins 12 of the IC handler 3 come into contact with electrode terminals 5b which are formed on, for example, the front surface of the wireless module 5 which is set on the placement stage 20. For example, the above-mentioned prescribed load is about 20 g per electrode terminal 5b.

The electrode terminals 5b which are formed on the wireless module 5 are supplied with, for example, a prescribed test signal or power from the contact pins 12 of the IC handler 3. When supplied with a prescribed signal or power, the wireless module 5 emits radio waves (in a millimeter wave band, for example) from an antenna 8 (an example of a first antenna). Furthermore, the antenna 8 receives radio waves emitted from a measurement antenna 43 of the testing device 1.

The anechoic box 40a is equipped with, on its internal wall surfaces, a radio wave absorbing body 47 for absorbing unnecessary radio waves coming from outside the anechoic box 40. The anechoic box 40 is an example of an antenna housing which houses the measurement antenna 43 of the testing device 1.

The anechoic box 40 is surrounded by the radio wave absorbing body 47. The anechoic box 40 is equipped with the measurement antenna 43 for receiving radio waves emitted from the wireless module 5 and emitting radio waves to the wireless module 5. The measurement antenna 43 is an example of a second antenna. A transmission antenna and a reception antenna may be provided separately as the measurement antenna 43.

Although not shown in any drawings, the anechoic box 40 is equipped with a module characteristics measuring unit for measuring, for example, the intensity of radio waves received or transmitted by the measurement antenna 43.

The measurement antenna 43 is mounted on a stage 43b (which is supported by four legs 43a) in such a manner that, for example, a central portion of the measurement antenna 43 is fixed. The measurement antenna 43 can receive radio waves coming from directions other than the vertical direction (Z-axis direction) when the four legs 43a are inclined. The module characteristics measuring unit measures the intensity of radio waves received by the measurement antenna 43 while varying the radio wave receiving direction by adjusting the inclination of the four legs 43a, whereby a radiation pattern of radio waves emitted from the antenna 8 can be acquired. The number of legs that support the stage 43b is not limited to four.

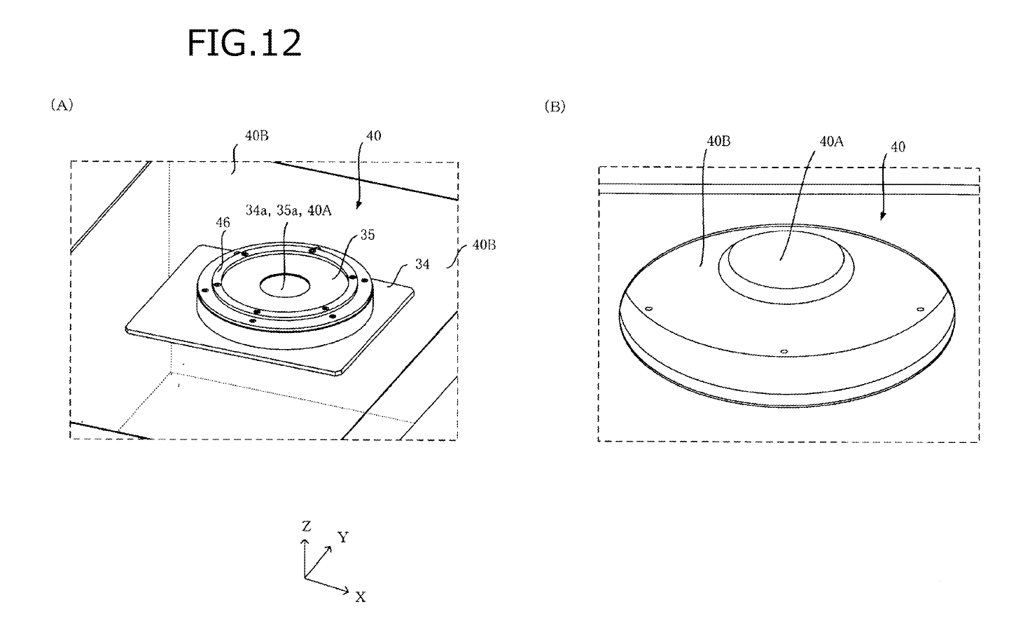

A ceiling wall 40B of the anechoic box 40 has an opening 40A (hole portion) which is opposed to an opening 20e of the placement stage 20. The ceiling wall 40B of the anechoic box 40 is also equipped with a placement stage auxiliary member 35 on which the placement stage 20 is placed. FIG. 12(A) is a schematic perspective view, as view from above, of the placement stage auxiliary member 35 which is set in the anechoic box 40. FIG. 12(B) is a schematic perspective view as viewed from below from inside the anechoic box 40. In FIG. 12(A), a part of the anechoic box 40, that is, the placement stage auxiliary member 35 and its neighborhood, is shown in an enlarged manner. In FIG. 12(B), another part of the anechoic box 40, that is, the opening 40A and its neighborhood, is shown in an enlarged manner.

As shown in FIGS. 1 and 12(A), a connection member 34 and the placement stage auxiliary member 35 are set on the ceiling wall 40B of the anechoic box 40. The connection member 34 is a member for connecting the placement stage auxiliary member 35 to the anechoic box 40 by screwing, for example. The placement stage auxiliary member 35 assists the mounting of the placement stage 20 on the anechoic box 40. The placement stage auxiliary member 35 is provided with a buffer member 46, and the placement stage 20 is mounted via the buffer member 46.

The connection member 34 and the placement stage auxiliary member 35 have respective openings 34a and 35a. The size of the opening 34a is approximately the same as that of the opening 40A of the anechoic box 40. The opening 40A of the anechoic box 40, the opening 34a of the connection member 34, and the opening 35a of the placement stage auxiliary member 35 are formed approximately at the same position in the XY plane and penetrate in the Z-axis direction.

As shown in FIG. 1, for example, the opening 40A is formed so as to have a larger XY sectional area in the outer wall surface of the anechoic box 40 than in its inner wall surface. Where there are no buffer-member-related restriction and a sufficiently large opening width can be secured for the opening 40A, the sectional areas in the outer and inner wall surfaces of the anechoic box 40 can be made approximately identical.

As shown in FIG. 12(B), the opening 40A which is formed through the ceiling wall 40B of the anechoic box 40 assumes a cylindrical shape, for example.

For example, the size of the opening 40A is determined according to the directivity direction of the antenna 8 and restrictions relating to the mounting of the buffer member 46 and the placement stage 20 on the ceiling wall 40B of the anechoic box 40. A gasket 32 shown in FIG. 1(A) is a kind of buffer member disposed between the anechoic box 40 and a test board 33. Usually, the test board 33 is not directly placed on the anechoic box 40 because various components are mounted on its surface that is opposed to the anechoic box 40. The gasket 32 produces a space between the anechoic box 40 and the test board 33. The size of the opening 40A is restricted by, for example, the manner of disposition of the gasket 32.

Although the measurement antenna 43 has been described mainly as a reception antenna, radio waves can be transmitted from a different direction from a receiving direction if a separate transmission antenna is disposed in the anechoic box 40. Radio waves emitted from the measurement antenna 43 are received by the antenna 8 of the wireless module 5.

As shown in FIG. 2 the placement stage 20, which, for example, is molded using a dielectric material (e.g., resin) so as to assume a socket shape, has a guide member 20b for guiding the wireless module 5 to be placed to inside the placement stage 20 and a seat member 20a on whose placement surface 20p the wireless module 5 is to be placed (contact is made between them). The seat member 20a has an opening 20e. The opening 20e is an example of a gap that is formed within a prescribed distance of the antenna 8 in its radio wave emitting direction in a state that the wireless module 5 is set on the placement surface 20p.

The opening 20e which is formed, for example, approximately at the center of the placement surface 20p of the seat member 20a is formed as a recess 20d, for example. A lid 20c is disposed so as to form a bottom surface 22 of the recess 20d. As described later, the opening 20e may be formed as a hole portion.

The recess 20d produces a gap that is formed within a prescribed distance of the antenna 8 which is installed on a mounting surface 5a of the wireless module 5 in a state that the wireless module 5 is set on the placement surface 20p of the seat member 20a. When the wireless module 5 is tested, the contact pins 12 of the IC handler 3 are brought into contact with the electrode terminals 5b of the wireless module 5 that is set on the placement stage 20.

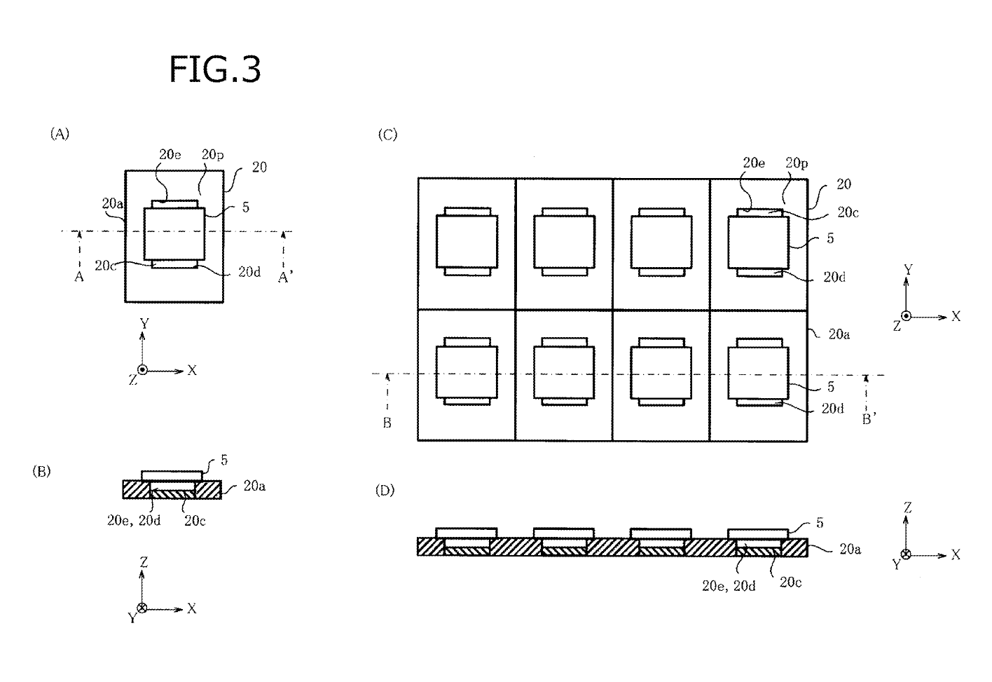

FIGS. 3(A)-3(D) are plan views and sectional views showing example shapes of placement stages 20 on which a wireless module or modules 5 are set. FIG. 3(A) is a plan view, as viewed from above (from the positive side in the Z-axis direction), of a placement stage 20 on which one wireless module 5 is set. FIG. 3(B) is a schematic sectional view of the placement stage 20 taken along line A-A′ in FIG. 3(A). FIG. 3(C) is a plan view, as viewed from above (from the positive side in the Z-axis direction), of a placement stage 20 on which plural wireless modules 5 are set. FIG. 3(D) is a schematic sectional view of the placement stage 20 taken along line B-B′ in FIG. 3(C). The guide member 20b is omitted in FIGS. 3(A)-3(D).

The plural wireless modules 5 are arranged in lattice form, for example; they may be arranged in another form. Although the placement stage 20 on which one wireless module 5 is set will mainly be described below, the description is also applicable to a case that plural wireless modules 5 are arranged.

Referring to FIGS. 3(A)-3(D), an opening 20e which is formed approximately at the center of the placement surface 20p of the seat member 20a is formed as a recess 20d which is defined by wall surfaces 21 (an example of a first surface) of the seat member 20a and a bottom surface 22 (an example of a second surface). The wall surfaces 21 are connected to the placement surface 20p. The bottom surface 22 is connected to the wall surfaces 21 and approximately opposed to the placement surface 20p.

For example, the bottom surface 22 of the recess 20d is formed by a lid 20c which is disposed in the opening 20e of the seat member 20a so as to be opposed to the test subject wireless module 5. The wall surfaces 21 of the recess 20d are connected to the placement surface 20p and the bottom surface 22 and is formed so as to extend, for example, in the Z direction which is perpendicular to the bottom surface 22 (XY surface).

The length, in one horizontal direction (in FIGS. 3(A)-3(D), the X-axis direction), of the opening 20e of the seat member 20a may be either greater or smaller than that of the wireless module 5. The length, in the other horizontal direction (in FIGS. 3(A)-3(D), the Y-axis direction), of the opening 20e of the seat member 20a may be either greater or smaller than that of the wireless module 5.

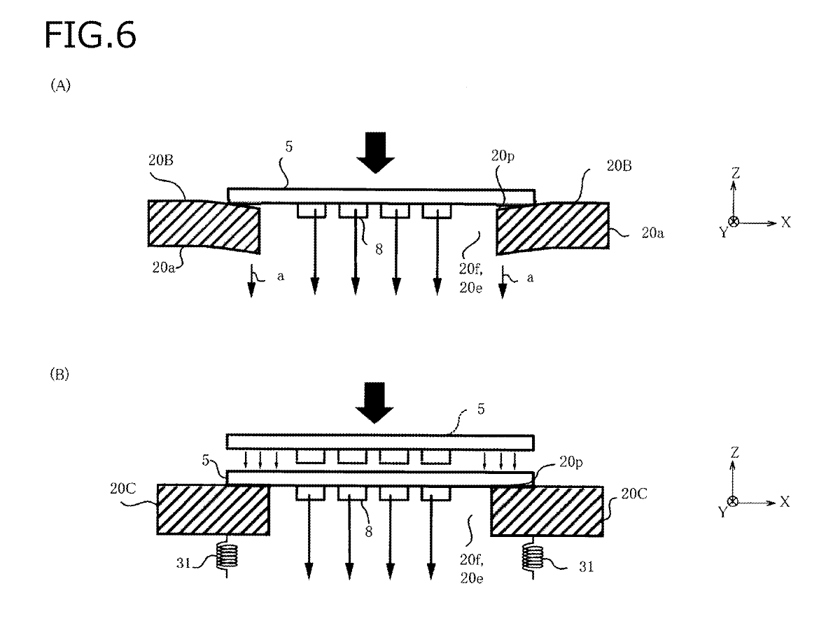

Next, consideration will be given to the specification of the opening 20e of the placement surface 20p of the placement stage 20. The expression “opening 20e” that encompasses the above-mentioned recess 20d which is defined by the wall surfaces 21 and the bottom surface 22 and a hole 20f (described later; see FIG. 6) which penetrates through the seat member 20a.

A condition that minimizes the interference that a signal reflected by peripheral structures (reflection wave) interferes with a signal emitted from the wireless module 5 (incident waves) is that the phase difference of the reflection wave from the incident wave is equal to, for example, about ¼ of the wavelength λ of a fundamental wave. The peripheral structures include the wall surfaces 21 of the seat member 20a and the bottom surface 22.

When the phase difference between a fundamental wave (sine wave) signal included in emitted radio waves and a reflection wave signal is about (¼)λ, the amplitude peak value of a composite wave of the incident wave and the reflection wave varies while assuming a sine waveform.

When the incident wave is a signal emitted from the antenna 8 of the wireless module 5 and the reflection wave is a signal reflected from a structure around the antenna 8, the amplitude, for example, of a composite wave varies. Therefore, the power peak value (the maximum amplitude value of a power waveform) varies depending on the presence/absence of a reflection wave. On the other hand, the shape (phase) of the composite wave of the incident wave and the reflection wave does not vary. Therefore, the directivity of the antenna 8 can be measured without being distorted in shape.

To give the placement stage 20 a shape that does not affect the radiation pattern of the antenna 8, the distance from the antenna 8 mounting surface 5a to a surface (e.g., bottom surface 22) including directions (e.g., X-axis direction and Y-axis direction) that are perpendicular to the directivity direction (e.g., Z-axis direction) is set, for example, in the following manner.

That is, the influences of reflection waves from the placement stage 20 can be minimized by disposing a surface including directions that are perpendicular to the directivity direction at a position that is distant from the mounting surface 5a by (¼)×(4n+1) times the wavelength λ that corresponds to a communication frequency used by the antenna 8 (n: integer).

A description will be made of an example case that a communication is performed in a millimeter wave frequency band.

For example, a millimeter wave band has a wavelength range of 1 to 10 mm. Therefore, the bottom surface 22 of the placement stage 20 may be disposed approximately at a position having a prescribed distance from the antenna 8 according to the wavelength λ of a signal used (condition (1)). The prescribed distance is given by the following Formula (1). When condition (1) is satisfied, the influences of reflection waves reflected from the bottom surface 22 on the module characteristics with involvement of the antenna 8 can be minimized.

(0.25 to 2.5 mm)×(4n+1) (1)

where n is an integer.

In designing the wireless module 5, what value in the range 0.25 to 2.5 mm should be used in Formula (1) is determined uniquely according to what value in, for example, a millimeter wave band wavelength range 1 to 10 mm is used as the wavelength λ. That is, the parenthesized length is set equal to λ/4.

As for directions other than the directivity direction of the antenna 8, the wall surfaces 21 of the placement stage 20 may be disposed at positions having a prescribed distance or more from the antenna according to the wavelength λ of a signal used (condition (2)). The prescribed distance is the same as the distance given by the above Formula (1). When condition (2) is satisfied, the influences of reflection waves reflected from the wall surfaces 21 on the module characteristics with involvement of the antenna 8 can be minimized.

Next, specific example shapes of the placement stage 20 will be described based on the above discussions.

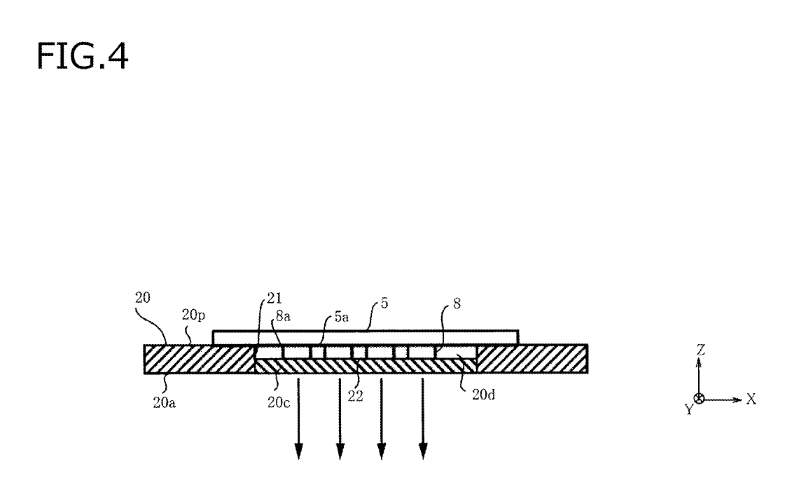

FIG. 4 is a sectional view showing an example shape of a placement stage 20 on which the wireless module 5 is set, and corresponds to FIG. 2(B). As shown in FIG. 4, the wireless module 5 is placed on the placement surface 20p of the seat member 20a of the placement stage 20 with its antenna 8 mounting surface 5a down. The mounting surface 5a of the wireless module 5 is in contact with the placement surface 20p which is located around the opening 20e.

The opening 20e of the seat member 20a has the wall surfaces 21 and the bottom surface 22 and is formed as the recess 20d which houses the antenna 8. As shown in FIG. 4, the lid 20c which is one of the members that form the recess 20d is disposed under the seat member 20a. The thickness (length in the Z-axis direction) of the lid 20c is equal to 2 mm, for example. As shown in FIG. 4, the directivity direction of the antenna 8 is downward (the direction toward the negative side of the Z axis; indicated by arrows in FIG. 4).

To test the wireless module 5, when the pusher 10 is lowered to push the contact pins 12 of the IC handler 3 and thereby exert a prescribed load on the wireless module 5, the mounting surface 5a of the wireless module 5 comes to be supported by the portion, around the opening 20e, of the seat member 20a. The portion, around the opening 20e, of the seat member 20a is so rigid as to bear the prescribed load, and hence the wireless module 5 is less prone to such deformation that approximately its central portion, for example, is warped downward.

The antenna 8 comes close to the surface of the lid 20c, that is, the bottom surface 22, while being opposed to it. Even in this case, if the above-mentioned condition (1) is satisfied, the influences of reflection waves on a signal component that is emitted from the antenna 8 in the directivity direction can be suppressed.

Gaps exist between the wall surfaces 21 of the recess 20d and ends 8a of the antenna 8. As a result, if the above-mentioned condition (2) is satisfied, the influences of reflection waves on signal components that are emitted from the antenna 8 in directions other than the directivity direction can be suppressed.

That is, by forming the recess 20d in the seat member 20a of the placement stage 20, degradation of the directivity of the antenna 8 due to the presence, around the antenna 8, of the dielectric material that forms the bottom surface 22 or the wall surfaces 21 can be suppressed.

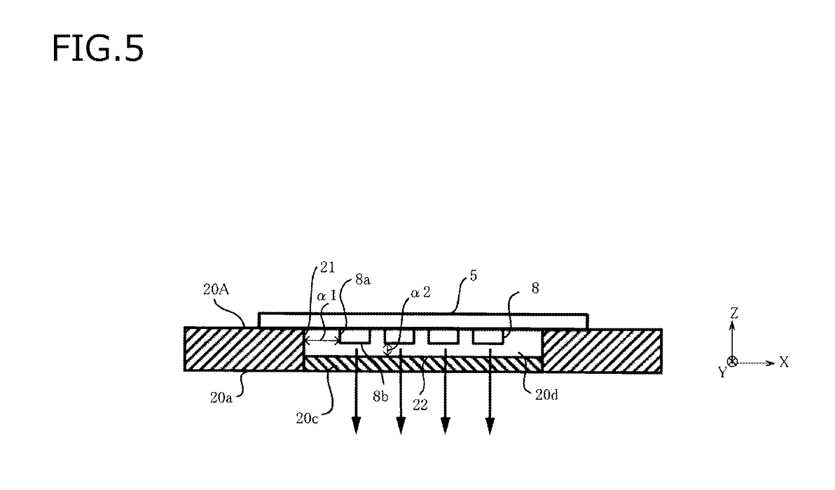

FIG. 5 is a sectional view showing a first modification (placement stage 20A), relating shape, of the placement stage 20 on which the wireless module 5 is set. In the placement stage 20A, the recess 20d is formed in such a manner that the distance between the bottom surface (front surface) 8b of the antenna 8 and the top surface of the lid 20c bottom surface 22) is equal to about 2 mm, for example. That is, in the placement stage 20A, the seat member 20a is thicker and the recess 20d where the antenna 8 is housed during a test is deeper than in the placement stage 20. A gap is formed in a prescribed range in the Z-axis direction under the antenna 8.

The recess 20d is formed in such a manner that the distance α1 between the ends 8a, in the horizontal direction (X-axis direction), of the antenna 8 and the wall surfaces 21 of the recess 20d is longer than or equal to 2.4 mm, for example. The thickness (length in the Z-direction) of the lid 20c is equal to 2 mm, for example, which is the same as in the placement stage 20 of the second example. The directivity direction of the antenna 8 is downward in FIG. 5 (the direction toward the negative side of the Z axis).

In this example, for example, the distance α2 (e.g., 2 mm) between the bottom surface 8b of the antenna 8 and the bottom surface 22 is close to approximately ¼ of a millimeter wave band wavelength λ (e.g., 8 mm). That is, in a state that the wireless module 5 is set on the placement surface 20p of the seat member 20a, the distance between the antenna 8 and the bottom surface 22 is approximately equal to the prescribed distance that is given by Formula (1). As a result, the influences of reflection waves on a signal component that is emitted from the antenna 8 in the directivity direction can be suppressed.

Furthermore, for example, the distance α1 (e.g., 2.4 mm or longer) between the wall surfaces 21 of the recess 20d and the ends 8a of the antenna 8 is longer than or equal to approximately ¼ of a millimeter wave band wavelength (e.g., 8 mm). That is, in a state that the wireless module 5 is set on the placement surface 20p of the seat member 20a, the distance between the antenna 8 and the wall surfaces 21 is longer than or equal to the prescribed distance that is given by Formula (1). As a result, the influences of reflection waves on signal components that are emitted from the antenna 8 in directions other than the directivity direction can be suppressed.

Since the gaps are formed in the prescribed ranges around the antenna 8, the generation of reflection waves by a resin material, for example, can be suppressed, whereby variations of the antenna characteristics and hence degradation of the module characteristics can be suppressed.

FIG. 6(A) is a sectional view showing a second modification (placement stage 20B), relating shape, of the placement stage 20 on which the wireless module 5 is set.

The modification of FIG. 6(A) is of a case that the placement stage 20B is made of a flexible material (e.g., rubber material or sponge material). A hole 20f is formed as the opening 20e so as to penetrate through the seat member 20a, for example, approximately at its center in the direction (Z-axis direction) that is perpendicular to the placement surface 20p. Since no part of the seat member 20a exists in the directivity direction of the antenna 8 because of the formation of the hole 20f, the influences of reflection waves on a signal emitted from the antenna 8 can be suppressed.

To test the wireless module 5, when the pusher 10 is lowered to push the contact pins 12 of the IC handler 3, the seat member 20a of the placement stage 20B being pushed via the wireless module 5 is warped so as to sink down (toward the negative side of the Z axis) in a well-balanced manner as indicated by arrows a in the figure. As a result, the wireless module 5 continues to extend horizontally instead of being warped downward. As a result, the wireless module 5 can be tested properly for its module characteristics while variations in the directivity direction are suppressed.

FIG. 6(B) is a sectional view showing a third modification (placement stage 20C), relating shape, of the placement stage 20 on which the wireless module 5 is set.

In the modification of FIG. 6(B), spring members 31 are disposed on the side opposite to the placement surface 20p of the seat member 20a. The spring members 31 have a function of a damper for buffering a load that is exerted on the placement stage 20C. The spring members 31 are resilient in the direction in which the placement surface 20p is pushed. Since the anechoic box 40 exists under the placement stage 20C (i.e., on the destination side in the pushing direction), even when the pusher 10 is lowered, the seat member 20a of the placement stage 20C receives resilient forces from the spring members 31 and is thereby prevented from sinking down.

Therefore, as in the modification of FIG. 6(A), the wireless module 5 continues to extend horizontally without being warped downward. As a result, the wireless module 5 can be tested properly for its module characteristics while variations in the directivity direction are suppressed.

The radio module placement stage 20 (20, 20A-20C) provides the following advantages.

Millimeter waves are electromagnetic waves (radio waves) in a wavelength range 1 to 10 mm (frequency range 30 to 300 GHz). To test the transmission/reception characteristics of a signal emitted from the antenna 8 of a wireless module 5 that uses a signal in a millimeter wave band, since its wavelength λ is very short, the signal phase difference varies to a large extent due to time differences between incident waves and reflection waves. Therefore, where no proper measure is taken for the placement stage 20 in terms of, for example, its shape signals reflected from peripheral structures affect the quality of an original signal emitted from the antenna 8 more remarkably when the signal is in a millimeter wave band than in a low frequency band.

The placement stage 20 can suppress degradation of the directivity of the antenna 8 even in a case that a wireless module 5 that uses a signal in a high frequency band (e.g., millimeter wave band) is tested with a member made of, for example, a dielectric material existing around the antenna 8. For example, the radiation characteristics of the antenna 8 can be improved by forming the recess 20d or the hole 20f in the seat member 20a of the placement stage 20. Furthermore, since the wireless module 5 is placed on the seat member 20a and gaps are formed within a prescribed distance of the antenna, a test of the wireless module 5 is less prone to be affected by reflection waves and the reliability of module characteristics obtained by the test can be increased.

Likewise, the testing device 1 incorporating the placement stage 20 can increase the reliability of module characteristics obtained by testing a wireless module 5 and hence enables a high-accuracy module characteristics measurement.

### Embodiment 2

The first embodiment is directed to the case that the directivity direction of the antenna 8 of the wireless module 5 is in the direction (Z-axis direction) that is perpendicular to the placement surface 20p of the placement stage 20. A second embodiment is directed to a case that the directivity direction of the antenna 8 of the wireless module 5 is in a direction that is deviated (inclined) by a prescribed angle from the direction (Z-axis direction) that is perpendicular to the placement surface 20p of the placement stage 20.

A testing device 1 according to the second embodiment is similar in configuration to the testing device 1 according to the first embodiment. Constituent elements having the same ones in the first embodiment will be given the same reference symbols as the latter and descriptions therefor will be omitted or simplified.

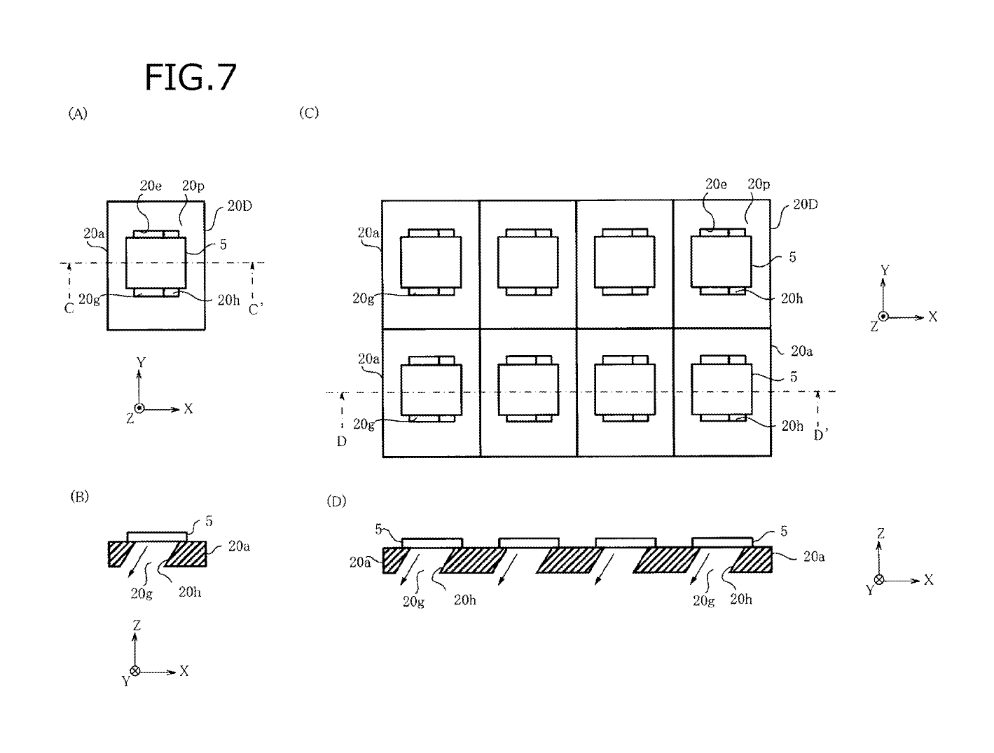

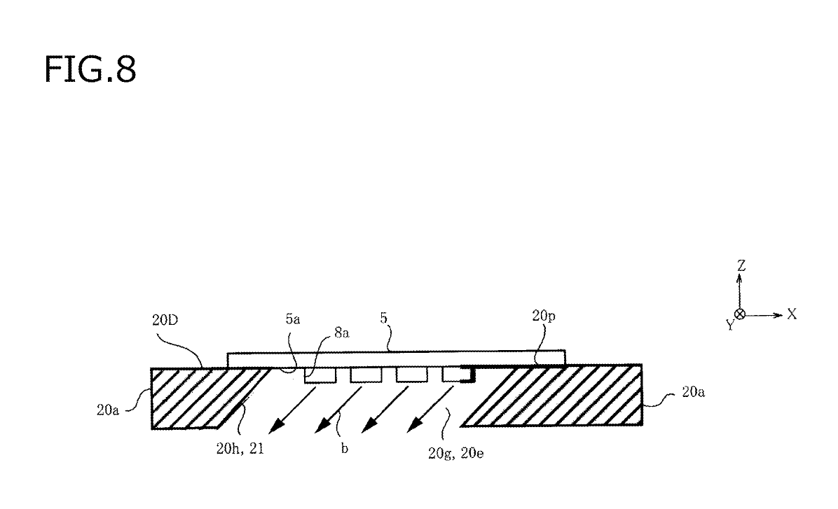

FIGS. 7(A)-7(D) are plan views and sectional views showing example shapes of placement stages 20D on which a wireless module or modules 5 are set. FIG. 7(A) is a plan view, as viewed from above (from the positive side in the Z-axis direction), of a placement stage 20D on which one wireless module 5 is set. FIG. 7(B) is a schematic sectional view of the placement stage 20D taken along line C-C′ in FIG. 7(A). FIG. 7(C) is a plan view, as viewed from above (from the positive side in the Z-axis direction), of a placement stage 20D on which plural wireless modules 5 are set. FIG. 7(D) is a schematic sectional view of the placement stage 20D taken along line D-D′ in FIG. 8(C). The guide member 20b is omitted in FIGS. 8(A)-8(D).

The plural wireless modules 5 are arranged in lattice form, for example; they may be arranged in another form. Although the placement stage 20D on which one wireless module 5 is set will mainly be described below, the description is also applicable to a case that plural wireless modules 5 are arranged.

The placement stage 20D, which, for example, is molded using a dielectric material (e.g., resin) so as to assume a socket shape, has a seat member 20a. The seat member 20a has an opening 20e. A hole 20g is formed, for example, approximately at the center of the seat member 20a as an example of an opening 20e so as to penetrate through the seat member 20a obliquely. That is, the hole 20g is inclined from the Z-axis direction by a prescribed angle.

Wall surfaces 21 (internal wall surfaces) of the hole 20g have slant surfaces 20h which extend in the directivity direction of the antenna 8. Alternatively, the opening 20e may be a recess 20d having a lid 20c rather than the hole 20g.

The length, in one horizontal direction (in FIGS. 7(A) and 7(B), the X-axis direction), of the hole 20g is smaller than that of the wireless module 5. The length, in the other horizontal direction (in FIGS. 7(A) and 7(B), the Y-axis direction), of the hole 20g is greater than that of the wireless module 5.

FIG. 8 is a sectional view showing an example shape of a placement stage 20D on which the wireless module 5 is set, and corresponds to FIG. 7(B). As in the first embodiment, the placement stage 20D has a seat member 20a on which the wireless module 5 is placed with its antenna 8 mounting surface 5a down.

The hole 20g is formed as the opening 20e through the seat member 20a, for example, approximately at the center. The wall surfaces 21 (internal wall surfaces) of the hole 20g have the slant surfaces 20h which extend in the directivity direction of a signal emitted from the antenna 8. The directivity direction of the antenna 8 is a direction (indicated by arrows b in FIG. 8) that goes obliquely downward from the antenna 8.

In the example of FIG. 8, approximately the same directivity is obtained for transmission and reception. Therefore, left-hand and right-hand wall surfaces 21 shown in FIG. 8 have respective slant surfaces 20h that are parallel with the directivity direction of transmission and reception.

To test the wireless module 5, the pusher 10 is lowered to push the contact pins 12 of the IC handler 3. When a prescribed load on the wireless module 5 via the contact pins 12, the mounting surface 5a of the wireless module 5 comes to be supported by the portion, around the opening 20e, of the seat member 20a. The portion, around the opening 20e, of the seat member 20a is so rigid as to bear the prescribed load, and hence the wireless module 5 is less prone to such deformation that approximately its central portion is warped downward.

Since the wall surfaces 21 of the hole 20g are inclined so as to be parallel with the directivity direction of the antenna 8 and the hole 20g is not associated with any part of the bottom surface the placement stage 20D, there are no influences of reflection waves of a signal component emitted in the directivity direction. When the wireless module 5 is placed on the placement stage 20D, since gaps exist between the wall surfaces 21 of the hole 20g and ends 8a of the antenna 8, the influences of reflection waves on signal components that are emitted directions other than the directivity direction can be suppressed. Furthermore, degradation of the directivity of the antenna 8 due to the presence, around the antenna 8, of the member made of a dielectric material, for example, can be suppressed.

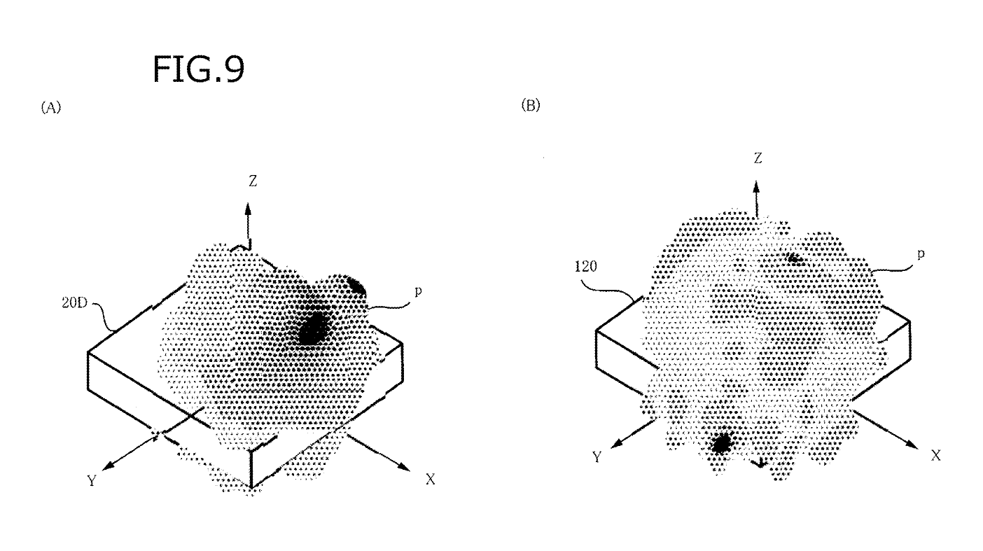

FIGS. 9(A) and 9(B) are schematic graphs showing example radiation patterns p of a signal emitted from the antenna 8.

In FIGS. 9(A) and 9(B), the X-axis direction is one horizontal direction of the placement stage 20D, the Y-axis direction is the other horizontal direction of the placement stage 20D, and the Z-axis direction is the vertical direction of the placement stage 20D. The antenna 8 mounting surface of the wireless module 5 is directed upward (toward the positive side of the Z-axis direction). Each radiation pattern p represents radio wave intensity by density (the radio wave intensity increases with increasing density). FIGS. 9(A) and 9(B) show characteristics of the antennas having the same directivity.

FIG. 9(A) shows a simulation result of a radiation pattern p of a signal that is emitted from the wireless module 5 set on the placement stage 20D.

FIG. 9(B) shows a simulation result of a radiation pattern p of a signal that is emitted from a wireless module set on a conventional placement stage 120. The placement surface, to contact the antenna mounting surface of the wireless module, of the placement stage 120 is not formed with a recess and is flat. That is, the thickness (length in the Z-axis direction) of the conventional placement stage 120 is uniform.

Where the placement stage 20D is used, as shown in FIG. 9(A), the radiation pattern p of a signal emitted from the antenna 8 is such that the radio wave intensity in the directivity direction of the antenna 8 is higher than that in the other directions. That is, as seen from FIG. 9(A), the direction that is tilted from the positive Z-axis direction toward the X-axis direction by a prescribed angle (e.g.,) 60° is the direction in which the radiation radio wave intensity is highest, that is, the directivity direction.

On the other hand, where the conventional placement stage 120 is used, as shown in FIG. 9(B), no radiation pattern p having high intensity in the directivity direction of the antenna is obtained. That is, it is understood that where the conventional placement stage 120 is used, the antenna radiation characteristics are degraded because no desired gaps are formed around the antenna 8.

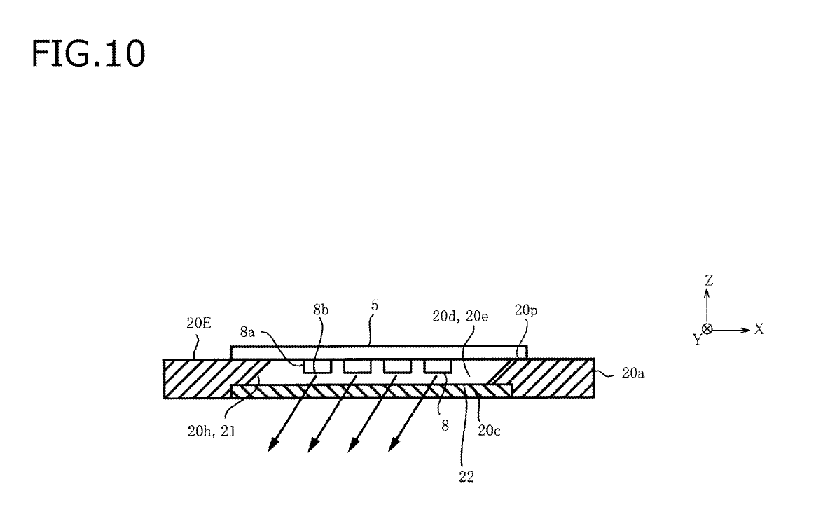

FIG. 10 is a sectional view showing a first modification (placement stage 20E), relating shape, of the placement stage 20D on which the wireless module 5 is set. In the placement stage 20E, wall surfaces 21 of a recess 20d (opening 20e) have slant surfaces 20h which extend in the directivity direction. A lid 20c which forms a bottom surface 22 of the recess 20d is disposed under the placement stage 20D as shown in FIG. 10. The thickness (length in the Z direction) of the lid 20c is 2 mm, for example.

The recess 20d is formed in such a manner that the distance from the bottom surface 8b of the antenna 8 to the top surface of the lid 20c (bottom surface 22) is equal to 2 mm, for example. The recess 20d is formed in such a manner that the distance between the ends 8a, in the horizontal direction (X-direction), of the antenna 8 and the slant surfaces 20h is longer than or equal to 2.4 mm, for example.

Since the distance (e.g., 2 mm) between the bottom surface 8b of the antenna 8 and the bottom surface 22 is approximately ¼ of a millimeter wave band wavelength (e.g., 8 mm), the influences of reflection waves on a signal component that is emitted from the antenna 8 in the directivity direction can be suppressed.

Furthermore, since the distance (e.g., 2.4 mm or longer) between the wall surfaces 21 (slant surfaces 20h) of the recess 20d and the ends 8a of the antenna 8 is longer than or equal to approximately ¼ of a millimeter wave band wavelength (e.g., 8 mm), the influences of reflection waves on signal components emitted in directions other than the directivity direction can be suppressed.

Since the placement stage 20E has the lid 20c, the seat member 20a for supporting the mounting surface 5a of the wireless module 5 is durable against a load.

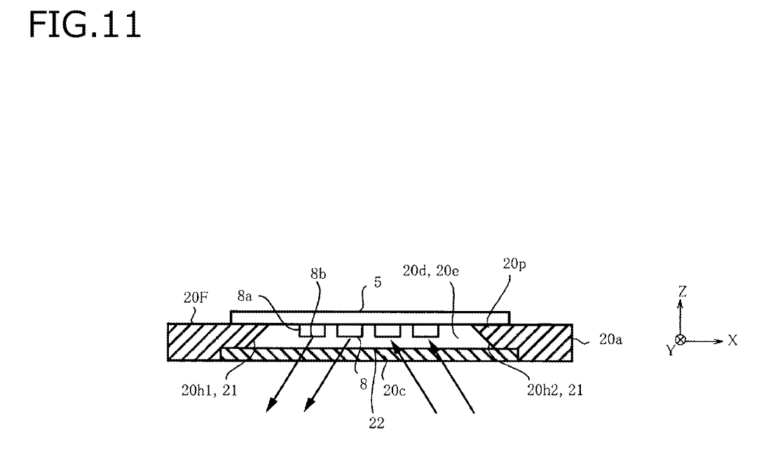

FIG. 11 is a sectional view showing a second modification (placement stage 20F), relating shape, of the placement stage 20D on which the wireless module 5 is set. The modification of FIG. 11 assumes that the antenna 8 have different directivity directions for transmission and reception.

Of the two side wall surfaces 21 of a recess 20d of the placement stage 20F, one surface is a slant surface 20h1 which extends in the directivity direction of a signal that is transmitted from the antenna 8 and the other surface is a slant surface 20h2 which extends in the directivity direction of a signal that is received by the antenna 8. That is, the wall surfaces 21 of the recess 20d are the slant surfaces 20h the distance between which increases downward. Alternatively, the slant surfaces 20h1 and 20h2 may extend in the direction of directivity for a reception signal and the direction of directivity for a transmission signal, respectively.

The placement stage 20F is the same as the placement stage 20E except that the former has the slant surfaces 20h the distance between which increases downward. For example, the distances between the above-mentioned positions and the above-mentioned thickness (e.g., 2 mm and 2.4 mm) are the same as in the placement stage 20E and hence will not be described here.

In this modification, radio waves can be transmitted to and received from different directions by disposing a reception antenna and a transmission antenna in the anechoic box 40 as measurement antennas 43.

According to this modification, the influences of reflection waves from the wall surfaces 21 of the opening 20e on a signal that is emitted from the antenna 8 in the directivity direction can be suppressed. Furthermore, the influences of reflection waves from the wall surfaces 21 of the opening 20e on a signal that comes in the directivity direction and is received by the antenna 8 can be suppressed.

### Embodiment 3

A third embodiment is directed to a case that the directivity direction of the antenna 8 of the wireless module 5 is in the direction (Z-axis direction) that is perpendicular to the placement surface of a placement stage or in a direction that is inclined from the perpendicular direction by a prescribed angle. In the third embodiment, the placement stage has a hole as the opening.

A testing device 1 according to the third embodiment is similar in configuration to the testing device 1 according to the first embodiment. Constituent elements having the same ones in the first embodiment will be given the same reference symbols as the latter and descriptions therefor will be omitted or simplified.

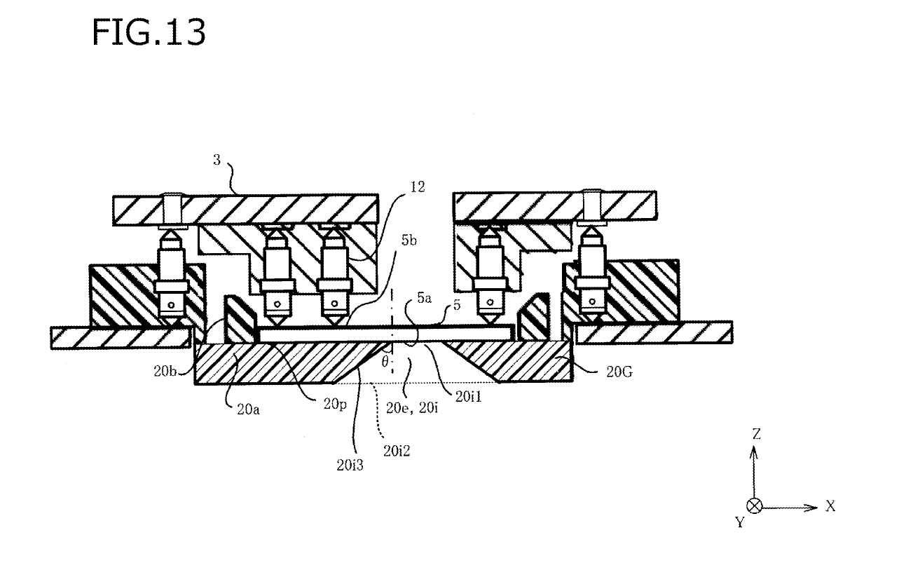

FIG. 13 is a partial, enlarged sectional view of an example of a placement stage 20G according to the third embodiment and its neighborhood. The placement stage 20G has a hole 20i as the opening 20e. In the hole 20i, the area of an opening end 20i1 (in the XY plane) located on the side of the wireless module 5 (on the positive side in the Z-axis direction) is smaller than that of an opening end 20i2 located on the side of the anechoic box 40 (on the negative side in the Z-axis direction). That is, the placement stage 20G is formed so as not to interfere with radio waves that are emitted from the antenna 8 and travel through the space while expanding. Slant surfaces 20i3 are formed as wall surfaces of the hole 20i so as to extend from the opening end 20i1 to the opening end 20i2.

Referring to FIG. 13, the angle θ that is formed by each slant surface 20i3 of the hole 20i and the opening end 20i1 or 20i2 is determined according to, for example, the radiation pattern of the antenna 8. In FIG. 13, the angle θ is the angle formed by the Z-axis direction and each slant surface 20i3. For example, where the half-value angle of the antenna directivity (radio wave radiation directions) is ±30°, the angle θ may be set at ±45° (±30° added with)±15° or larger. With this measure, the probability that a dielectric member exists in radio wave radiation directions can be reduced further. Thus, module characteristics can be measured with their degradations suppressed by reducing variations of the antenna characteristics.

Referring to FIG. 13, the difference between the areas of the opening ends 20i1 and 20i2 may be made as large as possible, which can increase the strength of the placement stage 20.

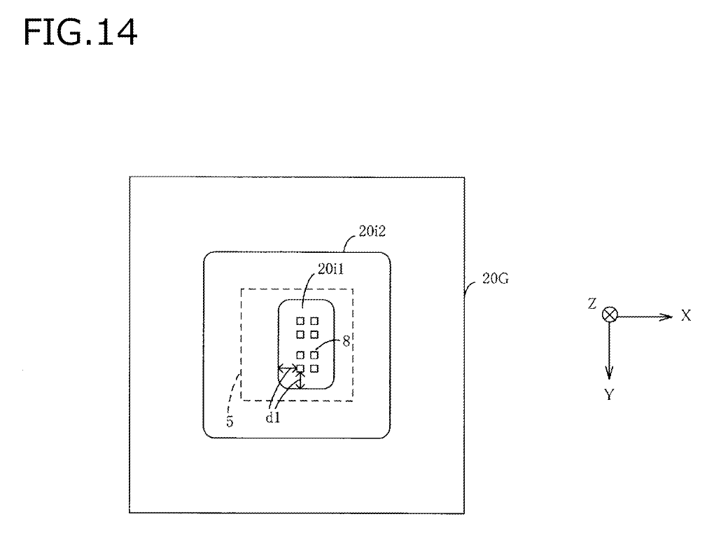

FIG. 14 is a plan view of the placement stage 20G as viewed from below (from the negative side in the Z-axis direction). The opening end 20i1 is the opening end of the hole 20i located on the positive side in the Z-axis direction. The opening end 20i2 is the opening end of the hole 20i located on the negative side in the Z-axis direction. When the placement stage 20G is viewed from below, the antenna 8 mounted on the wireless module 5 is seen in the opening end 20i1. Although in FIG. 14 the opening ends 20i1 and 20i2 are approximately rectangular, they may be formed in another shape (e.g., approximately circular shape).

As shown in FIG. 14, for example, the antenna 8 has eight antenna elements, that is, two 2×2 patch antennas. Each patch antenna may have a shape other than 2×2, and the number of patch antennas is not limited to two.

The distance d1 between each antenna element and the opening end 20i1 is set longer than or equal to, for example, λ/2 where λ is the wavelength of corresponding to a communication frequency used by the antenna 8. With this measure, the influences of reflection waves from the wall surfaces (slant surfaces 20i3) of the placement stage 20G and the variation of the radiation impedance for the antenna 8 can be suppressed.

In FIG. 14, an example setting d=λ/2 is made. In this case, since the portion to be pushed by the contact pins 12 is relatively wide, the degradation of emitted radio waves can be suppressed and the durability of the placement stage 20G against pushing force can be made high.

According to the placement stage 20G, since no dielectric material (e.g., resin material) exists on the destination side in the radio wave emission direction of the antenna 8, that is, on the Z-axis positive side of the antenna 8, reduction of the intensity of emitted radio waves and deformation of the radiation pattern can be suppressed.

Next, modifications of the hole 20i will be described.

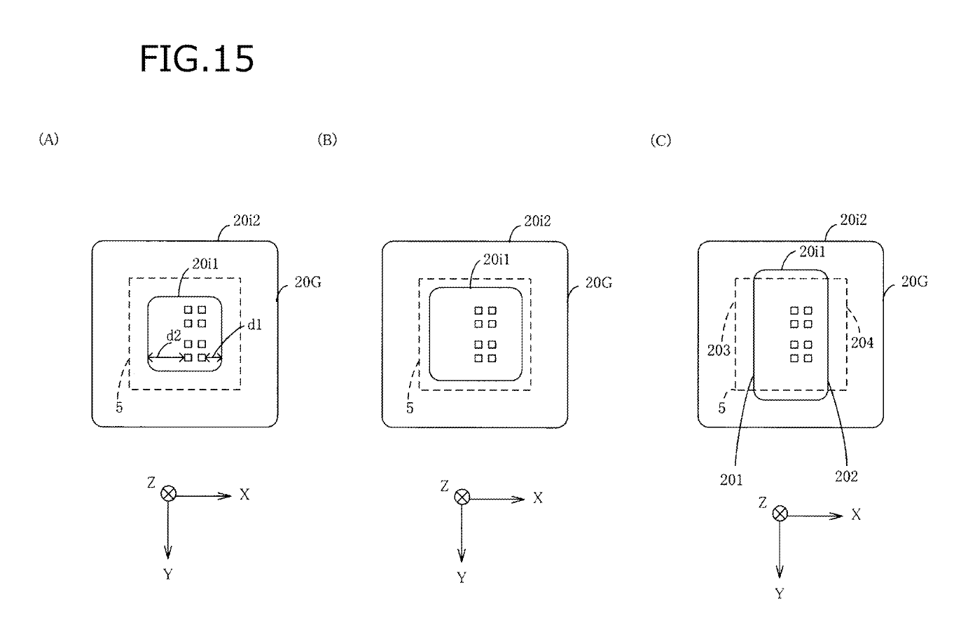

FIGS. 15(A)-15(C) are plan views showing modifications, in structure, of the hole 20i.

In a first modification shown in FIG. 15(A), the center of the wireless module 5 and the centers of the opening ends 20i1 and 20i2 in the XY plane are set so as to approximately coincide with each other. Referring to FIG. 15(A), antenna elements are arranged in the Y-axis direction in two columns. The distance d2 between the antenna elements belonging to the column located on the positive side in the X-axis direction and the opening end 20i1 is approximately equal to λ/2, and the distance d2 between the antenna elements belonging to the column located on the negative side in the X-axis direction and the opening end 20i1 is longer than or equal to about λ/2.

As described above, the center of the antenna 8 may be deviated from that of the opening end 20i1. Also in this case, contact pins 12 (see FIG. 13) push the wireless module 5 in a wider area on the positive side in the X-axis direction than on the negative side in the X-axis direction. Therefore, the wireless module 5 can be pressed against the placement stage 20G uniformly.

In a second modification shown in FIG. 15(B), the center of the wireless module 5 and the centers of the opening ends 20i1 and 20i2 in the XY plane are set so as to approximately coincide with each other. Referring to FIG. 15(B), the distance between the antenna elements of the antenna 8 and the opening end 20i1 is longer than or equal to about λ/2. As shown in FIG. 15(B), the area of the opening end 20i1 is somewhat smaller than that of the mounting surface 5a of the wireless module 5. In this case, as shown in FIG. 15(B), the opening end 20i1 is included in the region corresponding to the mounting surface 5a. Therefore, the hole 20 is formed so as to be larger than in the case of FIG. 15(A) so that the contact pins 12 can press the wireless module 5 against the placement stage 20G. In this case, the interference between radio waves emitted from the antenna 8 and the dielectric member can be reduced further, whereby variations of the antenna characteristics can be suppressed and hence the accuracy of measurement on the wireless module 5 can be increased.

In a third modification shown in FIG. 15(C), the length of two confronting sides (201 and 202) of the opening end 20i1 is greater than that of two sides (203 and 204) of the wireless module 5 that are parallel with the two sides of the opening end 20i1. In this case, the wireless module 5 is pushed by contact pins 12 near the two confronting sides (201 and 202) of the wireless module 5. The wireless module 5 is not pushed by any contact pins 12 near the sides other than these two sides. Referring to FIG. 15(C), the distance between the antenna elements of the antenna 8 and the opening end 20i1 is longer than or equal to about λ/2.

Therefore, regions where contact pins 12 come into contact with the wireless module 5 exist adjacent to the two ends of its mounting surface 5a in the Y-axis direction. No regions where contact pins 12 come into contact with the wireless module 5 exist adjacent to the two ends of its mounting surface 5a in the X-axis direction. Even in this case, since the wireless module 5 can be fixed using the regions of the mounting surface 5a that are adjacent to its two respective ends in the Y-axis direction, the interference between radio waves emitted from the antenna 8 and the dielectric member can be reduced, whereby variations of the antenna characteristics can be suppressed and hence the accuracy of measurement on the wireless module 5 can be increased.

As described above, even where the hole 20i is longer than the opening end 20i1 in either direction (e.g., Y-axis direction) in the XY plane, the wireless module 5 can be fixed by pushing it and its module characteristics can be measured.

According to this embodiment, since the hole 20i is formed taking into consideration radio waves that are emitted from the antenna 8 and travel through the space while expanding, the interference between emitted radio waves and the dielectric portion of the placement stage 20G can be suppressed. Therefore, variations of the antenna characteristics can be suppressed and hence the accuracy of measurement and testing on the wireless module 5 can be increased.

Conventional IC sockets are used for measuring characteristics of signals that are output from module terminals, and are not for measurement of a module incorporating an antenna (refer to Referential Patent document, for example).

Referential Patent document: JP-A-2009-245889

In contrast to the conventional IC sockets, the placement stage 20i according to the embodiment is shaped taking into consideration that it is intended for measurement of characteristics of a wireless module 5 incorporating an antenna 8. Degradation of the accuracy of measurement and testing on a wireless module 5 can be reduced by suppressing variations of the antenna characteristics.

### Embodiment 4

A fourth modification is a modification of the third embodiment. In the fourth modification, characteristics of a module incorporating an antenna are measured without using the anechoic box 40, that is, using a radio wave absorbing body that is not part of the anechoic box 40.

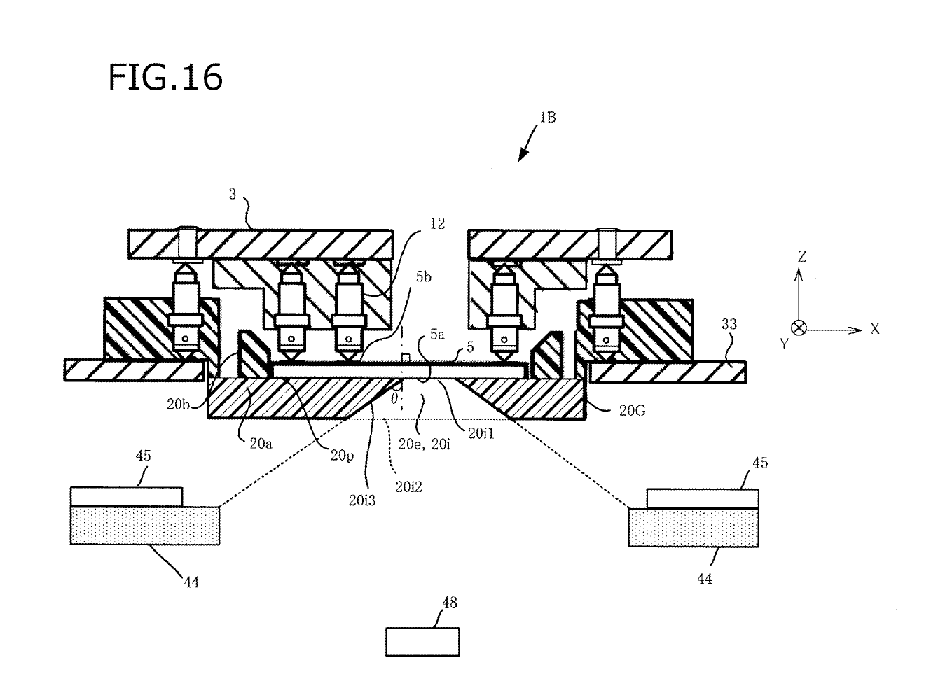

FIG. 16 is a sectional view showing an example configuration of part of a testing device 1B including the placement stage 20G according to the fourth embodiment. The testing device 1B is not equipped with the anechoic box 40 shown in FIG. 1 and is equipped with a radio wave absorbing body 44, an acrylic plate 45, and a measuring device 48. Constituent elements having the same ones in the testing device 1 shown in FIG. 1 or the placement stage 20G shown in FIG. 13 will be given the same reference symbols as the latter and descriptions therefor will be omitted or simplified.

The radio wave absorbing body 44 absorbs radio waves reflected from the measuring device 48 and thereby reduces radio waves that travel from the measuring device 48 toward the wireless module 5. The acrylic plate 45 supports the radio wave absorbing body 44 and fixes its position. For example, the measuring device 48 is configured so as to include the above-mentioned measurement antenna 43 and a module characteristics measuring unit for measuring the intensity of radio waves transmitted from or to be received by the measurement antenna 43.

As shown in FIG. 16, the radio wave absorbing body 44, the acrylic plate 45, and the measuring device 48 are disposed below the placement stage 20G (i.e., on the negative side in the Z-axis direction). The ends, on the side of the center of the antenna 8 in the X-axis direction, of the radio wave absorbing body 44 are located, for example, approximately at positions on respective extensions of the slant surface 20i3 of the hole 20i. This makes it possible to suppress the interference that reflection waves emitted from the measuring device 48 interfere with radio waves emitted from the placement stage 20G can be suppressed. The distance between a test board 33 and the acrylic plate 45 may be set small as long as the placement stage 20G receives no interference.

According to the testing device 1B which is reduced in size, characteristics of the wireless module 5 incorporating the antenna 8 can be measured without using the anechoic box 40. Although radio waves emitted from the wireless module 5 travel through the space while spreading, reflection waves or radiation waves from the measuring device 48 are reduced by the radio wave absorbing body 44, whereby variations of the antenna characteristics can be suppressed and hence the accuracy of measurement on the wireless module 5 can be increased.

### Embodiment 5

In the first to fourth embodiments, the wireless module is pushed by the contact pins, whereby the wireless module is fixed to the placement stage and the placement stage is fixed to the test board 33. In a fifth embodiment, a module socket to which a wireless module 5 is fixed by plural members using hooks will be described.

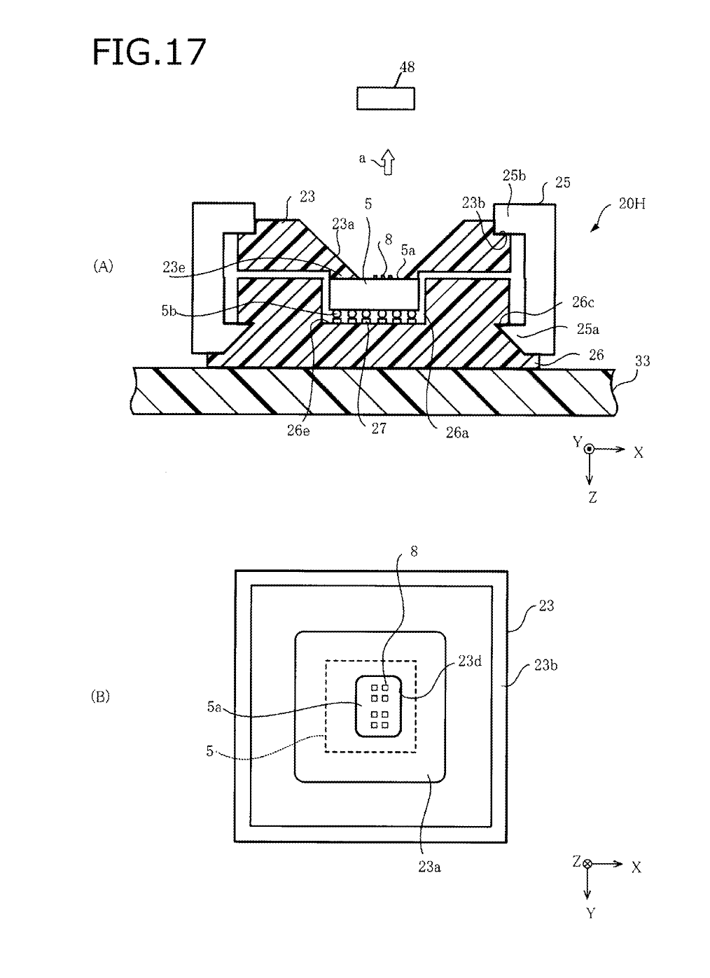

In the fifth embodiment, radio waves are emitted from an antenna 8 in a direction indicated by arrow a in FIG. 17(A). For example, disposed on the destination side in the direction indicated by arrow a is the measuring device 48 shown in FIG. 16 or the anechoic box 40 which houses the device for measuring module characteristics shown in FIG. 1 (e.g., measurement antenna 43 and module characteristics measuring unit). For example, module characteristics are measured by the same method as the measuring method of each of the above embodiments.

FIGS. 17(A) and 17(B) are a sectional view and a plan view, respectively, showing the shape of a module socket 20H and examples of members around the module socket 20H. FIG. 17(A) shows a cross section of the module socket 20H as viewed from the front side (from the positive side in the Y-axis direction). FIG. 17(B) shows the shape of a socket lid 23 when the module socket 20H of FIG. 17(A) is viewed from above (from the negative side in the Z-axis direction).

The top surface (XY plane; located on the negative side in the Z-axis direction) of a wireless module 5 is mounted with an antenna 8 which emits radio waves in the Z-axis direction, that is, in the direction that is approximately perpendicular to a mounting surface 5a.

The module socket 20H is configured so as to include a base 26, the socket lid 23, and hooks 25. The base 26 is mounted on a test board 33 which supplies power to the wireless module 5 and serves for input/output of signals. For example, the test board 33 is equipped with a connector that is connected to the measuring device 48 or a power source (not shown) and electronic components (e.g., capacitors and a power source IC) as external components of the wireless module 5.

The base 26 is formed with a recess 26a which houses the wireless module 5. The wireless module 5 is placed on a placement surface 26e which is the bottom surface of the recess 26a. Plural conductive pins 27 to contact respective electrode terminals (balls) 5b of the wireless module 5 housed in the recess 26a are arranged on the placement surface 26e of the base 26. The conductive pins 27 project from the placement surface 26e. The plural conductive pins 27 are connected to, for example, signal lines or power lines of the test board 33.

The socket lid 23 is brought into contact with the mounting surface 5a of the wireless module 5 so as to push the wireless module 5 which is set on the base 26. The socket lid 23 is formed with a projection 23e approximately at the center, and an opening 23a (hole portion) is formed so as to penetrate through the recess 23e in the Z-axis direction. The XY sectional shape of the opening 23a may be rectangular, circular, or of some other shape.

The opening 23a has a small opening area at the bottom (on the positive side in the Z-axis direction) and a large opening area at the top (on the positive side in the Z-axis direction). The inner wall surfaces of the opening 23a are slant surfaces that are inclined from the Z-axis direction by 45°, for example. The distance d1 between a bottom opening edge 23d which defines the smallest-area opening end and the elements of the antenna 8 is longer than or equal to λ/2, for example, where λ is the wavelength of radio waves emitted from the wireless module 5.

The minimum angle of the opening 23a depends on, for example, the radio wave radiation pattern of the antenna 8. For example, where the half-value angle of the antenna directivity is ±30°, the angle of the opening 23a is set at ±45° (the half-value angle added with)±15° or larger. This makes it possible to attain both of high workability and high strength of the module socket 20H.

The projection 23e of the socket lid 23 pushes the wireless module 5 downward (toward the positive side in the Z-axis direction) so that regions, close to the four respective sides, of the top surface (i.e., the surface on the negative side in the Z-axis direction) of the wireless module 5 receive even forces. For example, where the antenna 8 is disposed approximately at the center of the wireless module 5, a peripheral portion of the wireless module 5 is pressed uniformly. For example, where the antenna 8 is disposed on the wireless module 5 so as to be deviated to one side, the projection 23e of the socket lid 23 is formed so that its bottom surface (i.e., the surface on the negative side in the Z-axis direction) has different areas of contact with the wireless module 5 on one side and the other side in the X-axis direction. Also in this case, the wireless module 5 is pressed uniformly by surfaces, having different areas, of the wireless module 5.

Each hook 25 has a pair of lock pieces 25a and 25b to be engaged with a hook counterpart portion 26c which is a step of the base 26 and a hook counterpart portion 23b which is a step of the socket lid 23, respectively. The hooks 25 fix the base 26 and the socket lid 23 to each other by nipping them. As a result, the wireless module 5 is held between the base 26 and the socket lid 23. Although in the example of FIG. 17(A) employs the two hooks 25, three or more hooks may be used.

Before a start of a module characteristics test, the wireless module 5 is housed in the recess 26a of the base 26 and the plural electrode terminals 5b are brought into contact with the plural respective conductive pins 27. The wireless module 5 is pressed by the projection 23e of the socket lid 23 and the hooks 25 nip the socket lid 23 and the base 26. As a result, the wireless module 5 is fixed in the module socket 20H.

In the module socket 20H, the influences of its members (e.g., resin members) can be suppressed. As a result, the accuracy of module characteristics measurement and testing on the wireless module 5 having the antenna 8 the direction of its directivity is in the direction that is approximately perpendicular to the antenna 8 mounting surface 5a can be increased. For example, the degree of lowering of the accuracy of the module characteristics measurement performed by a measuring device (e.g., module characteristics measuring unit or measuring device 48) which is disposed on the Z-axis negative side of the module socket 20H can be reduced.

Since the wireless module 5 is pressed uniformly by the projection 23e of the socket lid 23, the electrode terminals 5b can come into contact with the respective conductive pins 27 satisfactorily. Therefore, for example, supply of power to the wireless module 5 or input/output of a signal to and from it can be performed stably.

Since electrical connections between the wireless module 5 and the base 26 are secured by the contact between the electrode terminals 5b and the conductive pins 27, the wireless module 5 which is a test subject can be replaced easily.

Since the hooks 25 fix the base 26 and the socket lid 23 to each other in such a manner that the wireless module 5 is held between them, the positional deviation of the wireless module 5 can be suppressed.

Since the wireless module 5 is housed in the recess 26a which is formed in the base 26, the module socket 20H can be made thinner.

Since the conductive pins 27 of the base 26 are connected to, for example, signal lines or power lines formed on the test board 33, a signal that is necessary for a test of the wireless module 5 can be input and output.

Furthermore, since the socket lid 23 is formed with the opening 23a, the members made of a dielectric (e.g., resin) can be spaced from the antenna 8 of the wireless module 5, whereby the influences of the antenna 8 on the module characteristics can be lowered. As a result, variations of the antenna characteristics can be suppressed and hence the accuracy of measurement and testing on the wireless module 5 can be increased.

The disclosure is not limited to the configurations of the above-described embodiments and can be applied to any configurations as long as they can realize the functions described in the claims or the functions of the configurations of the embodiments.

### (Outline of One Mode of Disclosure)

A first module socket of the disclosure includes:

a seat member that includes a placement surface configured to come into contact with a mounting surface, mounted with an antenna, of a wireless module having the antenna; and

a gap formed within a prescribed distance of the antenna in a radio wave radiation direction in a state that the wireless module is set on the placement surface.

A second module socket of the disclosure is based on the first module socket, and is such that:

the seat member includes a first surface that is connected to the placement surface; and

the gap includes a hole portion that penetrates through the seat member.

A third module socket of the disclosure is based on the first module socket, and is such that:

the seat member includes:
a first surface that is connected to the placement surface;
a second surface that is connected to the first surface and is opposed to the placement surface; and

the gap includes a recess that is formed by the first surface and the second surface.

A fourth module socket of the disclosure is based on the third module socket, and is such that in a state that the wireless module is set on the placement surface, a distance from the antenna to the first surface is longer than or equal to a distance that is approximately given by (¼)×λ×(4n+1), where λ is a wavelength of radio waves transmitted from or received by the antenna and n is an integer.

A fifth module socket of the disclosure is based on the third or fourth module socket, and is such that in a state that the wireless module is set on the placement surface, a distance from the antenna to the second surface is equal to a distance that is approximately given by (¼)×λ×(4n+1), where λ is a wavelength of radio waves transmitted from or received by the antenna and n is an integer.

A sixth module socket of the disclosure is based on the third or fourth module socket, and is such that the first surface includes a slant surface formed so as to be parallel with a directivity direction of the antenna.

A seventh module socket of the disclosure is based on the sixth module socket, and is such that in a case that the directivity direction of the antenna is in approximately the same direction for transmission and reception of radio waves, the first surface includes a slant surface formed so as to be parallel with approximately the same direction.

An eighth module socket of the disclosure is based on the sixth module socket, and is such that in a case that the directivity direction of the antenna is different for transmission and reception of radio waves, the first surface includes:

a slant surface formed so as to be parallel with a first directivity direction for transmission; and

a slant surface formed so as to be parallel with a second directivity direction for transmission.

A ninth module socket of the disclosure is based on any one of the first to eighth module sockets, and is such that the seat member is resilient in a direction in which the placement surface is pushed.

A 10th module socket of the disclosure is based on the second module socket, and is such that:

the first surface includes a slant surface formed so as to be parallel with a directivity direction of the antenna; and

the hole portion includes:
a first opening end located on a side of the placement surface; and
a second opening end located on a side opposite to the placement surface and being larger in area than the first opening end.

An 11th module socket of the disclosure is based on the 10th module socket, and is such the slant surfaces includes an inclination, inclining with respect to an axis that is perpendicular to the placement surface, the inclination being determined according to a half-value angle of the antenna.

A 12th module socket of the disclosure is based on the 10th or 11th module socket, and is such in a state that the wireless module is set on the placement surface, the distance from the antenna to the first surface is longer than or equal to a distance that is approximately given by (½)×λ, where λ is a wavelength of radio waves transmitted from or received by the antenna.

A 13th module socket of the disclosure is based on the 12th module socket, and is such that in a state that the wireless module is set on the placement surface, the first opening end is located in such a range as to be opposed to the wireless module.

A 14th module socket of the disclosure is based on the 12th module socket, and is such in a state that the wireless module is set on the placement surface, both edges, arranged in a first direction, of the first opening end are opposed to the wireless module and both edges, arranged in a second direction, of the first opening end are not opposed to the wireless module.

A wireless module testing device of the disclosure includes:

the module socket according to any one of the first to 14th module sockets;

contacts that are in contact with respective electrode terminals of the wireless module that is set on the module socket, and supply a prescribed signal or power to the wireless module;

a pusher that presses the contacts against the wireless module;

a second antenna that receives a radio wave emitted from a first antenna mounted on the wireless module or emits a radio wave toward the first antenna; and

an antenna housing that is surrounded by a radio wave absorbing body, is opposed to the module socket, and houses the second antenna.

A wireless module testing method of the disclosure includes:

setting a wireless module on the module socket according to any one of the first to 14th module socket;

bringing contacts, for supplying a prescribed signal or power to the wireless module, to come into contact with respective electrode terminals of the wireless module that is set on the module socket;

pressing the contacts against the wireless module; and

receiving a radio wave emitted from a first antenna mounted on the wireless module or emitting a radio wave toward the first antenna by a second antenna that is housed in an antenna housing which is surrounded by a radio wave absorbing body and opposed to the module socket.

The present application is based on Japanese Patent Application No. 2013-043494 filed on Mar. 5, 2013, the disclosure of which is incorporated herein by reference.

### INDUSTRIAL APPLICABILITY

The disclosure is useful when applied to module sockets, devices for testing a wireless module, etc. that can increase the reliability of module characteristics obtained by testing a wireless module.

### DESCRIPTION OF SYMBOLS

1, 1B: Testing device
3: IC handler
5: Wireless module
5a: Mounting surface
5b: Electrode terminal
8: Antenna
8a: End of antenna
8b: Bottom surface of antenna
10: Pusher
12: Contact pin
20, 20A, 20B, 20C, 20D, 20E, 20F, 20G, 120: Placement stage
20H: Module socket
20a: Seat member
20b: Guide member
20c: Lid
20d: Recess
20e: Opening
20g, 20f, 20i: Hole
20i1, 20i2: Opening end
20h, 20h1, 20h2, 20i3: Slant surface
20p: Placement surface
21: Wall surface
22: Bottom surface
23: Socket lid
23a: Opening
23b: Hook counterpart portion
23d: Opening edge
23e: Projection
25: Hook
25a, 25b: Lock piece
26: Base
26a: Recess
26c: Hook counterpart portion
26e: Placement surface
27: Conductive pin
31: Spring member
32: Gasket
33: Test board
34: Connection member
34a: Opening
35: Placement stage auxiliary member
35a: Opening
40: Anechoic box
40A: Opening
40B: Ceiling wall
43: Measurement antenna
43a: Four legs
43b: Stage
46: Buffer member
47: Radio wave absorbing body
48: Measuring device

1. A module socket, comprising:
a seat member that comprises a placement surface configured to contact with a mounting surface, mounted with an antenna, of a wireless module having the antenna; and
a gap formed within a prescribed distance from the antenna in a radio wave radiation direction, in a state that the wireless module is set on the placement surface.

2. The module socket according to claim 1, wherein the seat member comprises a first surface that is connected to the placement surface; and
wherein the gap comprises a hole portion that penetrates through the seat member.

3. The module socket according to claim 1, wherein the seat member comprises:
a first surface that is connected to the placement surface; and
a second surface that is connected to the first surface and is opposed to the placement surface; and
wherein the gap comprises a cavity that is formed by the first surface and the second surface.

4. The module socket according to claim 3,
wherein in the state that the wireless module is set on the placement surface, the prescribed distance from the antenna to the first surface is longer than or equal to a first distance that is approximately given by (¼)×λ×(4n+1), where λ, is a wavelength of radio waves transmitted from or received by the antenna and n is an integer.

5. The module socket according to claim 3, wherein in the state that the wireless module is set on the placement surface, the prescribed distance from the antenna to the second surface is equal to a second distance that is approximately given by (¼)×λ×(4n+1), where λ is a wavelength of radio waves transmitted from or received by the antenna and n is an integer.

6. The module socket according to claim 3, wherein the first surface comprises a slant surface formed so as to be parallel with a directivity direction of the antenna.

7. The module socket according to claim 6, wherein in a case that the directivity direction of the antenna for transmission of radio wave is the approximately same directivity direction of the antenna for reception of radio wave, the first surface comprises a slant surface formed so as to be parallel with approximately the same direction.

8. The module socket according to claim 6, wherein in a case that the directivity direction of the antenna for transmission of radio wave is different from the directivity direction of the antenna for reception of radio wave, the first surface comprises;
a slant surface formed so as to be parallel with the directivity direction of the antenna for transmission of radio wave; and
a slant surface formed so as to be parallel with a second directivity direction for transmission the directivity direction of the antenna for reception of radio wave.

9. The module socket according to claim 1, wherein the seat member is resilient in a direction in which the placement surface is pushed.

10. The module socket according to claim 2, wherein the first surface comprises a slant surface formed so as to be parallel with a directivity direction of the antenna; and
wherein the hole portion comprises:
a first opening end located on a side of the placement surface; and
a second opening end located on a side opposite to the placement surface and being larger in area than the first opening end.

11. The module socket according to claim 10,
wherein an inclination of the slant surface is determined according to a half-value angle of the directivity direction of the antenna with respect to an axis that is perpendicular to the placement surface.

12. The module socket according to claim 10, wherein in all the state that the wireless module is set on the placement surface, the prescribed distance from the antenna to the first surface is longer than or equal to a first distance that is approximately given by (½)×λ, where λ is a wavelength of radio waves transmitted from or received by the antenna.

13. The module socket according to claim 12, wherein in the state that the wireless module is set on the placement surface, the first opening end is located to be opposed to the wireless module.

14. The module socket according to claim 12, wherein in the state that the wireless module is set on the placement surface, first both edges, arranged in a first direction, of the first opening end are opposed to the wireless module, and second both edges, arranged in a second direction, of the first opening end are not opposed to the wireless module.

15. A wireless module testing device comprising:
contacts that are in contact with respective electrode terminals of a wireless module that is set on a module socket and supply a prescribed signal or power to the wireless module;
a pusher that presses the contacts against the wireless module;
a second antenna that receives a radio wave emitted from a first antenna mounted on the wireless module or emits a radio wave toward the first antenna; and
an antenna housing that is surrounded by a radio wave absorbing body, is opposed to the module socket, and houses the second antenna, wherein
the module socket, comprising:
a seat member that comprises a placement surface configured to contact with a mounting surface, mounted with the first antenna, of the wireless module having the first antenna; and
a gap formed within a prescribed distance from the first antenna in a radio wave radiation direction, in a state that the wireless module is set on the placement surface.

16. A wireless module testing method comprising:
setting a wireless module on a module socket;
bringing contacts, for supplying a prescribed signal or power to the wireless module, to contact with respective electrode terminals of the wireless module that is set on the module socket;
pressing the contactors against the wireless module; and
receiving a radio wave emitted from a first antenna mounted on the wireless module or emitting a radio wave toward the first antenna by a second antenna that is housed in an antenna housing which is surrounded by a radio wave absorbing body and opposed to the module socket, wherein
the module socket, comprising:
a seat member that comprises a placement surface configured to contact with a mounting surface, mounted with the first antenna, of the wireless module having the first antenna; and
a gap formed within a prescribed distance from the first antenna in a radio wave radiation direction, in a state that the wireless module is set on the placement surface.
